(19) United States
(12) Patent Application Publication
(10) Pub. No.: US 2025/0079308 A1
(43) Pub. Date: Mar. 6, 2025

(54) ELECTRONIC DEVICE

(71) Applicant: Advanced Semiconductor Engineering, Inc., Kaohsiung (TW)

(72) Inventors: Hao-Chih HSIEH, Kaohsiung (TW); Chun-Kai CHANG, Kaohsiung (TW); Chao Wei LIU, Kaohsiung (TW)

(73) Assignee: Advanced Semiconductor Engineering, Inc., Kaohsiung (TW)

(21) Appl. No.: 18/239,726

(22) Filed: Aug. 29, 2023

(51) Int. Cl. H01L 23/528; H01L 23/498; H01L 25/16

(52) U.S. Cl. CPC H01L 23/5286; H01L 23/49816; H01L 23/49833; H01L 23/49838; H01L 25/165; H01L 24/16; H01L 2224/16227; H01L 2224/16235; H01L 2924/1431; H01L 2924/19105

(57) ABSTRACT

An electronic device is disclosed. The electronic device includes a first electronic component and a first interposer. The first electronic component is disposed under the interposer and includes a logic circuit and a power delivery circuit disposed between the interposer and the logic circuit. The interposer and the power delivery circuit are collectively configured to function as a power delivery structure which is electrically connected to the logic circuit.

### BACKGROUND

### 1. Field of the Disclosure

The present disclosure generally relates to an electronic device.

### 2. Description of the Related Art

High performance computing (HPC) systems for electronic devices impose challenging demands on power consumption and heat dissipation characteristics of power supply units. Power routing paths for transmitting power signals are usually provided by a system board, over which several dies are mounted. Layout design may be constrained by the need to minimize electromagnetic interference between power signals and non-power signals (e.g., electrical signals), which can limit the ability to miniaturize the system board.

The voltage and power requirements of the dies vary, and the inevitable expansion in the total number and variety of dies has led to a corresponding increase in the number of power routing paths. One approach to providing more power routing paths is to provide power through the backside surface of a die. However, integrating dies with different dimensions (e.g., thickness) poses a significant challenge in designing power transmission traces.

### SUMMARY

In some embodiments, an electronic device includes a first electronic component and an interposer. The first electronic component is disposed under the interposer and includes a logic circuit and a power delivery circuit disposed between the interposer and the logic circuit. The interposer and the power delivery circuit are collectively configured to function as a power delivery structure which is electrically connected to the logic circuit.

In some embodiments, an electronic device includes a first electronic component, a first interposer, and a second interposer. The first electronic component includes a logic circuit and a first power delivery circuit electrically connected to the logic circuit. The first interposer is disposed over the first electronic component and electrically connected to the first power delivery circuit. The second interposer is disposed over the first electronic component and electrically connected to the first power delivery circuit. The second interposer is spaced apart from the first interposer.

In some embodiments, an electronic device includes an electronic component and an interposer. The electronic component includes a logic circuit and a first power delivery circuit electrically connected to the logic circuit. The interposer is disposed over the electronic component and includes a second power delivery circuit electrically connected to the first power delivery circuit. An upper surface of the first power delivery circuit is without vertically overlapping the interposer.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of an electronic device according to some embodiments of the present disclosure.

FIG. 2A illustrates an enlarged view of interposers as shown in FIG. 1 according to some embodiments of the present disclosure.

FIG. 2B illustrates an interposer according to some embodiments of the present disclosure.

FIG. 3 illustrates a cross-sectional view of an electronic device according to some embodiments of the present disclosure.

FIG. 4 illustrates a cross-sectional view of an electronic device according to some embodiments of the present disclosure.

FIG. 5 illustrates a cross-sectional view of an electronic device according to some embodiments of the present disclosure.

FIG. 6 illustrates a cross-sectional view of an electronic device according to some embodiments of the present disclosure.

FIG. 7 illustrates a cross-sectional view of an electronic device according to some embodiments of the present disclosure.

FIG. 8 illustrates a cross-sectional view of an electronic device according to some embodiments of the present disclosure.

FIG. 9 illustrates a cross-sectional view of an electronic device according to some embodiments of the present disclosure.

FIG. 10A, FIG. 10B, FIG. 10C, and FIG. 10D illustrate one or more stages of an example of a method for manufacturing an electronic device according to some embodiments of the present disclosure.

FIG. 11 illustrates an electronic device according to some embodiments of the present disclosure.

### DETAILED DESCRIPTION

Common reference numerals are used throughout the drawings and the detailed description to indicate the same or similar components. Arrangements of the present disclosure will be readily understood from the following detailed description taken in conjunction with the accompanying drawings.

The following disclosure provides many different arrangements, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include arrangements in which the first and second features are formed or disposed in direct contact and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

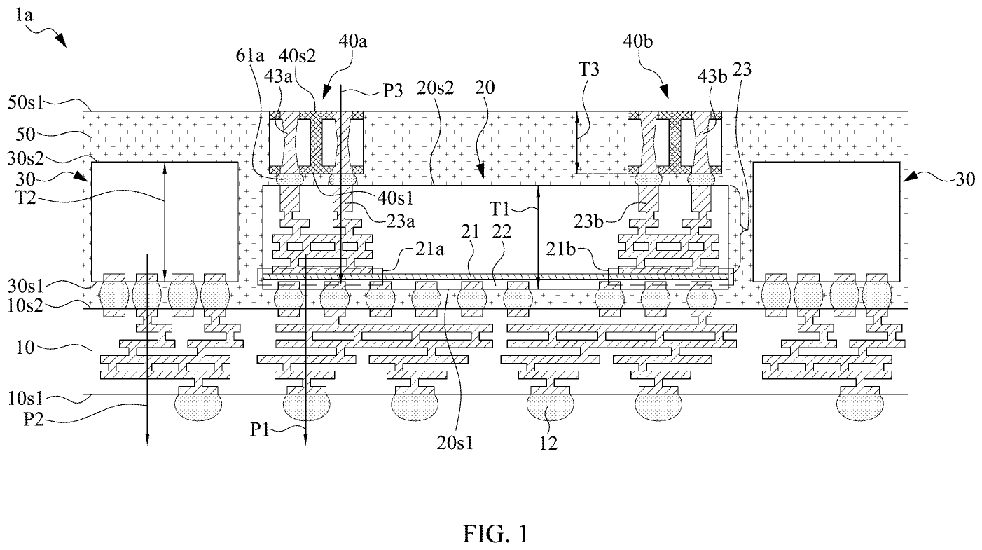

FIG. 1 illustrates a cross-sectional view of an electronic device 1a according to some embodiments of the present disclosure. In some embodiments, the electronic device 1a may include a circuit structure 10, an electronic component 20, at least one electronic component 30, interposers 40a and 40b, and an encapsulant 50.

The circuit structure 10 may include, for example, a printed circuit board, such as a paper-based copper foil laminate, a composite copper foil laminate, or a polymer-impregnated glass-fiber-based copper foil laminate. The circuit structure 10 may include a redistribution layer (RDL) or traces for electrical connection between components. The circuit structure 10 can be replaced by other suitable carriers, such as a lead frame. The circuit structure 10 may include a surface 10s1 (or a lower surface) and a surface 10s2 (or an upper surface) opposite to the surface 10s1.

The electronic device 1a may include electrical connectors 12. The electrical connector 12 may be disposed on or under the surface 10s1 of the circuit structure 10. The electrical connector 12 may be configured to electrically connect the electronic device 1a and an external device (not shown).

The electronic component 20 may be disposed on or over the surface 10s2 of the circuit structure 10. The electronic component 20 may include an active component that relies on an external power supply to control, output, or modify electrical signals. For example, the electronic component 20 may include a processor, a controller, a memory, an input/output (I/O) buffer, etc. The electronic component 20 may include a system on chip (SoC), a central processing unit (CPU), a microprocessor unit (MPU), a graphics processing unit (GPU), a microcontroller unit (MCU), an application-specific integrated circuit (ASIC), a field-programmable gate array (FPGA), or another type of integrated circuit. In some embodiments, the electronic component 20 may be electrically connected to the circuit structure 10 by a flip-chip technique. In other embodiments, the electronic component 20 may be electrically connected to the circuit structure 10 by a wire bond or other suitable techniques. The electronic component 20 may have a surface 20s1 (or a lower surface) and a surface 20s2 (or an upper surface) opposite to the surface 20s1. The surface 20s1 may also be referred to as an active surface, which IC circuits are formed on. The surface 20s2 may also be referred to as a passive surface, which power passes through. In some embodiments, the surface 20s2 of the electronic component 20 may be polished or ground so that the thickness of the electronic component 20 may be controlled or modified.

The electronic component 20 may include a logic circuit 21, a redistribution structure 22, and a power delivery circuit 23 (or a backside power delivery network). The logic circuit 21 may be disposed adjacent to the surface 20s1 of the electronic component 20. The logic circuit 21 may include one or more ICs which are formed within a semiconductor substrate. The logic circuit 21 may be configured to receive power (or a power signal) and generate a signal (or a non-power signal), such as an input/output (I/O) signal. The logic circuit 21 may be configured to perform two or more functions. For example, the logic circuit 21 may include a circuit region 21a and a circuit region 21b distinct from the circuit region 21a. In some embodiments, the trace (or transistor) of the circuit region 21a may be electrically connected to the trace (or transistor) of the circuit region 21b. In some embodiments, the circuit region 21a may be configured to perform a function different from that of the circuit region 21b.

The redistribution structure 22 may be disposed between the logic circuit 21 and the surface 20s1 of the electronic component 20. The redistribution structure 22 may be a front redistribution structure of the electronic component 20. The redistribution structure 22 may be configured to receive and/or transmit a signal (e.g., I/O signal), which may include or be composed of alternating current (AC). For example, a path P1 (e.g., a signal path) may pass through the redistribution structure 22 and the surface 20s1 of the electronic component 20. The path P1 may pass through the circuit structure 10. In some embodiments, the redistribution structure 22 may be configured to receive and/or transmit power.

The power delivery circuit 23 may be disposed between the logic circuit 21 and the surface 20s2. In some embodiments, the power delivery circuit 23 may be configured to receive and/or transmit power, which may include or be composed of direct current (DC), to the logic circuit 21. For example, a path P3 (e.g., a power path) may pass through the power delivery circuit 23 through the surface 20s2 of the electronic component 20. In some embodiments, the power delivery circuit 23 may include a redistribution structure, which may include one or more conductive traces and conductive vias embedded within one or more dielectric layers. In some embodiments, the power delivery circuit 23 may include a portion 23a and a portion 23b. The portion 23a may be electrically connected to the circuit region 21a. The portion 23b may be electrically connected to the circuit region 21b. As described above, since the surface 20s2 may be polished or ground, the thickness of the power delivery circuit 23 may be controlled or modified, which influences the number of layers of conductive traces and/or conductive vias of the power delivery circuit 23. In some embodiments, the voltage of the power signal transmitted by the redistribution structure 22 may be less than the voltage of the power signal transmitted by the power delivery circuit 23. In some embodiments, the current/power of the power signal transmitted by the redistribution structure 22 may be greater than the current/power of the power signal transmitted by the power delivery circuit 23.

The electronic component 30 may be disposed on or over the surface 10s2 of the circuit structure 10. In some embodiments, the electronic component 30 may be configured to function as a passive component, which does not rely on an external power supply. For example, the electronic component 30 may be configured to adjust or modify the impedance. In some embodiments, the electronic component 30 may be configured to amplify, adjust, or modify a signal of the electronic component 20. The electronic component 30 may include a resistor, a capacitor, an inductor, or a combination thereof. In some embodiments, the electronic component 30 may be electrically connected to the circuit structure 10 by a flip-chip technique. The electronic component 30 may include a surface 30s1 (or a lower surface) and a surface 30s2 (or an upper surface) opposite to the surface 30s1. The surface 30s1 may function as a surface through which a signal passes. For example, a path P2 (e.g., a signal path) may pass through the surface 30s1 of the electronic component 30. The path P2 may pass through the circuit structure 10. The surface 30s2 may function as a backside surface, and no power or signal passes through. The electronic component 30 may have a larger dimension in comparison with the electronic component 20. For example, the electronic component 20 may have a thickness T1 between the surfaces 20s1 and 20s2, the electronic component 30 may have a thickness T2 between the surfaces 30s1 and 30s2, and the thickness T2 may be greater than the thickness T1. The surface 30s2 may be located at a height (or an elevation) greater or higher than that of the surface 20s2. Unlike the electronic component 20, the surface 30s2 of the electronic component 30 cannot be ground or polished. Otherwise, the electrical property of the electronic component 30 will be changed or destroyed, leading to the dysfunction of an electronic device.

The interposers 40a and 40b may be disposed on or over the surface 20s2 of the electronic component 20. Each of the interposers 40a and 40b may be electrically connected to the electronic component 20. Each of the interposers 40a and 40b may be configured to receive and/or transmit power (or a power signal) to the electronic component 20 through the surface 20s2. In some embodiments, each of the interposers 40a and 40b may be configured to receive and/or transmit a non-power signal. In some embodiments, each of the interposers 40a and 40b may be electrically connected to the electronic component 20 through electrical connectors 61a. The electrical connector 61a may include a solder element. The solder element may include solder materials, which may include alloys of gold and tin solder or alloys of silver and tin solder, or other suitable materials. The interposer 40a may be spaced apart from the electronic component 20 by the electrical connectors 61a. In other embodiments, each of the interposers 40a and 40b may be electrically connected to the electronic component 20 by a hybrid-bonding technique, which involves a bonding between metal materials and a bonding between dielectric materials.

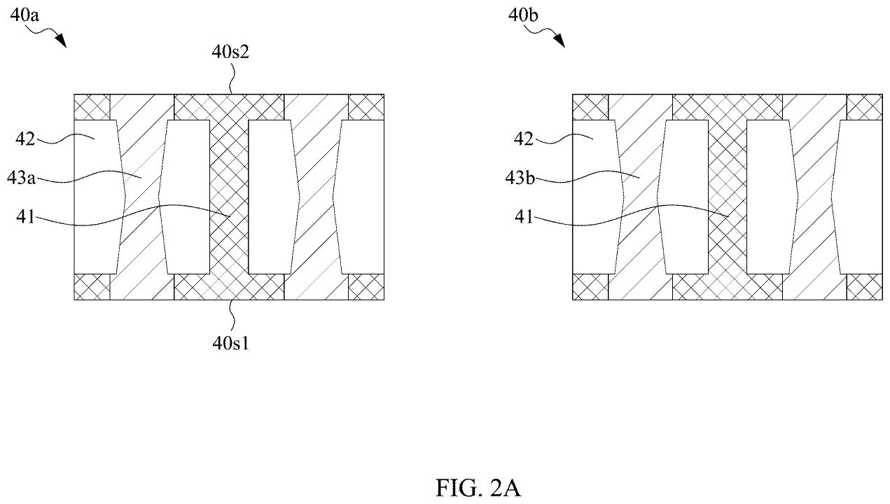

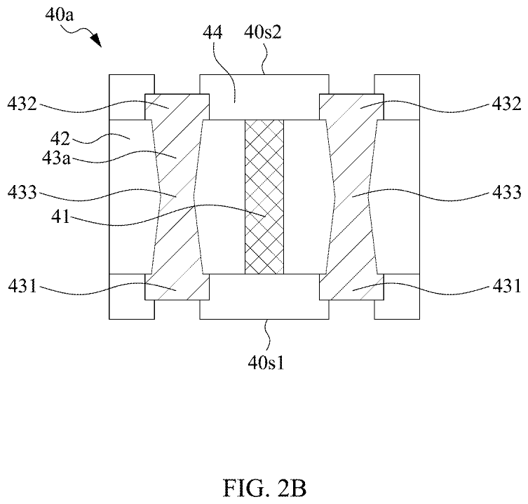

Please refer to FIG. 2A, which illustrates the enlarged view of the interposers 40a and 40b; each of the interposers 40a and 40b may include a conductive structure embedded in one or more dielectric layers. For example, the interposer 40a may include a dielectric structure 41, a dielectric structure 42, and a power delivery circuit 43a. The dielectric structure 41 may encapsulate the dielectric structure 42. The dielectric structure 42 may encapsulate the power delivery circuit 43a. The dielectric structure 42 may be a core layer, which may be formed before the dielectric structure 41. In some embodiments, the dielectric structures 41 and 42 may include polyimide or other suitable materials. The dielectric structures 41 and 42 may include the same material. The thickness of the dielectric structure 42 may be greater than that of the dielectric structure 41. The power delivery circuit 43a may include a lower portion and an upper portion (not annotated), both of which are tapered towards each other. The power delivery circuit 43a may include terminals on the lower portion and the upper portion. The power delivery circuit 43a may include a conductive via between the terminals. The power delivery circuit 43a may be configured to receive and/or transmit power to the circuit region 21a of the logic circuit 21. The quantity of conductive layers of the interposer 40a is different from that of the power delivery circuit 23.

The interposer 40b may include the dielectric structure 41, the dielectric structure 42, and a power delivery circuit 43b. The power delivery circuit 43b may be encapsulated by the dielectric structures 41 and 42. In some embodiments, the power delivery circuit 43b may include a lower portion and an upper portion (not annotated), both of which are tapered towards each other. The power delivery circuit 43b may include terminals on the lower portion and the upper portion. The power delivery circuit 43b may be configured to receive and/or transmit power to the circuit region 21b of the logic circuit 21.

Referring to FIG. 2B, the interposer 40a may further include a dielectric layer 44. The power delivery circuit 43a may include terminals 431 and 432. The terminal 431 may be exposed from the surface 40s1. The terminal 432 may be exposed from the surface 40s2. The terminals 431 and 432 may include, for example, conductive pads. The dielectric layer 44 may cover a portion of the terminals 431 and/or 432. The dielectric layer 44 may include, for example, a solder resist or other suitable materials. The power delivery circuit 43a may include a conductive via 433 between the terminals 431 and 432.

Referring back to FIG. 1, the interposer 40a may cover a portion of the electronic component 20. The interposer 40b may cover a portion of the electronic component 20. A portion of the surface 20s2 of the electronic component 20 may be exposed by the interposers 40a and 40b. The interposer 40a (or interposer 40b) may have a thickness T3. In some embodiments, the thickness T2 may be less than a sum of the thicknesses T1 and T3. The interposer 40a may have a surface 40s1 (or a lower surface) and a surface 40s2 (or an upper surface) opposite to the surface 40s1. In some embodiments, the surface 40s2 of the interposer 40a may be defined as an upper surface of the power delivery circuit 43a or an upper surface of the dielectric structure 41 as shown in FIG. 2A. In some embodiments, the surface 40s2 may be located at a height, with respect to the surface 10s2 of the circuit structure 10, higher than the surface 30s2 of the electronic component 30. The interposer 40a and the power delivery circuit 23 may collectively configured to function as a power delivery structure which is electrically connected to the logic circuit 21 and provide the logic circuit with power.

In some embodiments, each of the power delivery circuits 43a and 43b may function as a part of a path to transmit power and thus ease the burden of the power delivery circuit 23. In this condition, some of the traces and/or vias of the power delivery circuit 23 may be reduced, leading to an improved yield during the formation of the power delivery circuit 23. Further, unlike a silicon interposer, which includes a redistribution structure formed within a semiconductor substrate, the interposers 40a and 40b may be produced or acquired at a relatively low cost, thereby reducing the cost of the electronic device 1a. Moreover, as mentioned above, the surface 30s2 of the electronic component 30 cannot be polished or ground. When the thickness of the electronic component 20 is lower than that of the electronic component 30, an additional conductive structure is required to compensate for the height difference between the electronic components 20 and 30 and function as a medium to transmit power between the electronic component 20 and an additional circuit structure which supplies power. As a result, the electronic component 30 can be free of being polished or ground. Further, the surface 30s2 is higher than the surface 20s2, which increases the transmission path of power between the surface 50s1 and the surface 20s2, and therefore increases the difficulty of forming routing traces to build a power delivery circuit. In this embodiment, the interposer 40a (or 40b) constitute a transmission path between the surface 50s1 and the surface 20s2 so that the power may be transmitted to the electronic component 20 through the interposer 40a (or 40b). In some embodiments, a portion of an upper surface of the power delivery circuit 23 (e.g., the upper surface of the portion 23b) may be exposed by the interposer 40a.

The encapsulant 50 may be disposed on or over the surface 10s2 of the circuit structure 10. The encapsulant 50 may encapsulate electronic component 20. The encapsulant 50 may be in contact with the surface 20s2 of the electronic component 20. The encapsulant 50 may cover the lateral surface (not annotated) of the electronic component 20. The encapsulant 50 may encapsulate the electronic component 30. The encapsulant 50 may be in contact with the surface 30s2 of the electronic component 30. The encapsulant 50 may encapsulate the interposers 40a and 40b. The encapsulant 50 may be disposed between the interposers 40a and 40b. A portion of the encapsulant 50 may be disposed within a gap between the interposer 40a (or interposer 40b) and the electronic component 20. The encapsulant 50 may include insulation or dielectric material. For example, the encapsulant 50 may include a molding compound. In some embodiments, the encapsulant 50 may be made of molding material that may include, for example, a Novolac-based resin, an epoxy-based resin, a silicone-based resin, or another suitable encapsulant. Suitable fillers may also be included, such as powdered SiO₂. The encapsulant 50 may have a surface 50s1 (or an upper surface). In some embodiments, the surface 50s1 of the encapsulant 50 may be substantially aligned with the surface 40s2 of the interposer 40a. The surface 40s2 of the interposer 40a may be exposed by the encapsulant 50. A distance between the surface 50s1 and the surface 30s2 may be greater than a distance between the surface 50s1 and the surface 20s2.

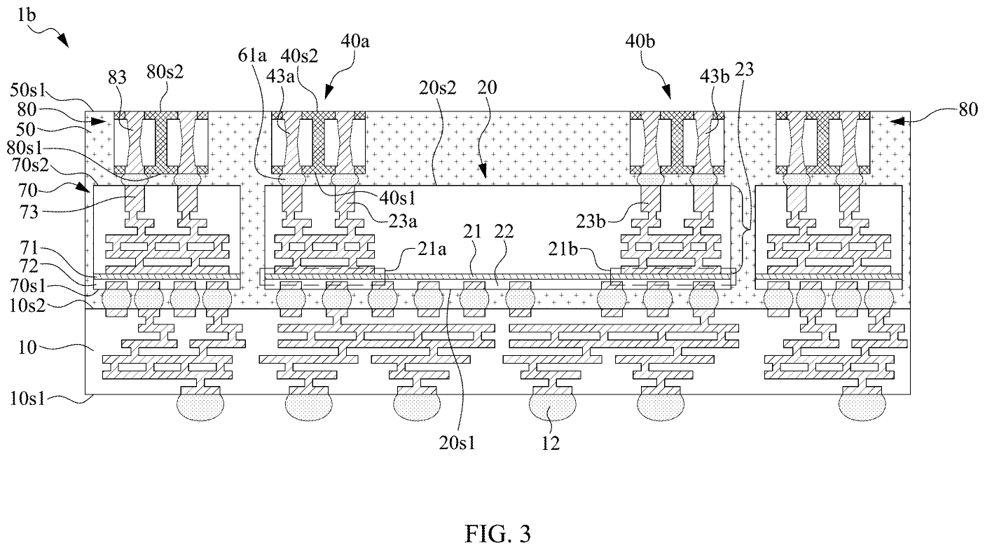

FIG. 3 illustrates a cross-sectional view of an electronic device 1b according to some embodiments of the present disclosure. The electronic device 1b is similar to the electronic device 1a as shown in FIG. 1, with differences therebetween as follows.

In some embodiments, the electronic device 1b may include an electronic component 70. The electronic component 70 may be disposed on or over the surface 10s2 of the circuit structure 10. The electronic component 70 may include an active component that relies on an external power supply to control, output, or modify electrical signals. For example, the electronic component 20 may include a processor, a controller, a memory, an input/output (I/O) buffer, etc. The electronic component 70 may include a system on chip (SoC), a central processing unit (CPU), a microprocessor unit (MPU), a graphics processing unit (GPU), a microcontroller unit (MCU), an application-specific integrated circuit (ASIC), a field-programmable gate array (FPGA), or another type of integrated circuit. In some embodiments, the electronic component 70 may be electrically connected to the circuit structure 10 by a flip-chip technique. The electronic component 70 may have a surface 70s1 (or a lower surface) and a surface 70s2 (or an upper surface) opposite to the surface 70s1. The surface 70s1 may also be referred to as an active surface, which IC circuits are formed on. The surface 70s2 may also be referred to as a passive surface, which power passes through.

The electronic component 70 may include a logic circuit 71, a redistribution structure 72, and a backside power delivery network 73. The logic circuit 71 may be disposed adjacent to the surface 70s1 of the electronic component 70. The logic circuit 71 may include one or more ICs, such as a logic circuit, a memory circuit, or other suitable circuits which are formed within a semiconductor substrate. The logic circuit 71 may be configured to receive power (or a power signal), and generate a signal (or a non-power signal), such as an input/output (I/O) signal.

The redistribution structure 72 may be disposed between the logic circuit 71 and the surface 70s1 of the electronic component 70. The redistribution structure 72 may be configured to receive and/or transmit a signal (e.g., I/O signal).

The backside power delivery network 73 may be disposed between the logic circuit 71 and the surface 70s2. In some embodiments, the backside power delivery network 73 may be configured to receive and/or transmit power. In some embodiments, the backside power delivery network 73 may include a redistribution structure, which may include one or more conductive traces and conductive vias embedded within one or more dielectric layers.

In some embodiments, the electronic device 1b may include an interposer 80. The interposer 80 may be electrically connected to the electronic component 70. The interposer 80 may be configured to receive and/or transmit power (or a power signal) to the electronic component 70 through the surface 70s2. The interposer 80 may include a power delivery circuit 83. The power delivery circuit 83 may be configured to receive and/or transmit power to the electronic component 70 through the surface 70s2. The interposer 80 may include a surface 80s1 and a surface 80s2 opposite to the surface 80s1. The surface 80s1 may be located at a height the same as that of the surface 40s1. The surface 80s2 may be located at a height the same as that of the surface 40s2.

In this embodiment, the electronic device 1b may include an additional interposer (e.g., interposer 80) disposed on an additional electronic component (e.g., electronic component 70). In this embodiment, some of the traces and/or vias of the backside power delivery network 73 may be reduced, leading to an improved yield during the formation of the backside power delivery network 73.

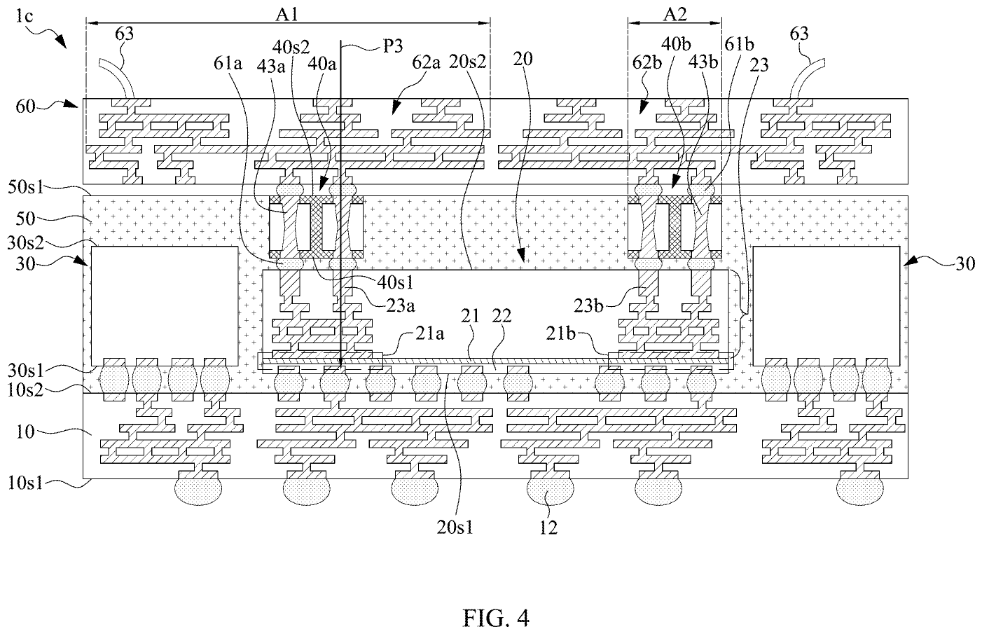

FIG. 4 illustrates a cross-sectional view of an electronic device 1c according to some embodiments of the present disclosure. The electronic device 1c is similar to the electronic device 1a as shown in FIG. 1, with differences therebetween as follows.

In some embodiments, the electronic device 1c may include a circuit structure 60. The circuit structure 60 may be disposed on or over the surface 50s1 of the encapsulant 50. The circuit structure 60 may cover a gap between the interposers 40a and 40b. The circuit structure 60 may be configured to transmit power (or a power signal) to the electronic component 20 through the interposer 40a and/or 40b. In some embodiments, the path P3 may further pass through the circuit structure 60. The circuit structure 60 may include a redistribution structure. The circuit structure 60 may be configured to receive power regulated from a power management integrated circuit (PMIC, not shown) and transmit regulated power to the electronic component 20. The circuit structure 60 may be electrically connected to the interposer 40a and/or 40b through electrical connectors 61b, which may include solder materials. In some embodiments, the circuit structure 60 may include a power delivery trace 62a (or a circuit region) and a power delivery trace 62b (or a circuit region) distinct from the power delivery trace 62a. The power delivery trace 62a may be electrically connected to the interposer 40a. The electronic device 1c may include electrical connectors 63. The electrical connector 63 may include a cable or other suitable elements. The electrical connector 63 may be configured to transmit power to the circuit structure 60 from an external power supply element. The power delivery trace 62b may be electrically connected to the interposer 40b. The power delivery trace 62a may define a projection area A1 onto or over the surface 10s2 of the circuit structure 10. The interposer 40a (or interposer 40b) may define a projection area A2 onto or over the surface 10s2 of the circuit structure 10. In some embodiments, the projection area A1 may be greater than the projection area A2. The circuit structure 60 may be a power board, which is configured to receive external power and integrate different power delivery traces (e.g., 62a and 62b). Further, the power delivery traces 62a and/or 62b may extend to the lateral surface or a periphery portion of the circuit structure 60 to facilitate in connection with external power supply elements (e.g., wire bonds, flexible printed circuit board, or other elements). The circuit structure 60 may be applicable to other embodiments.

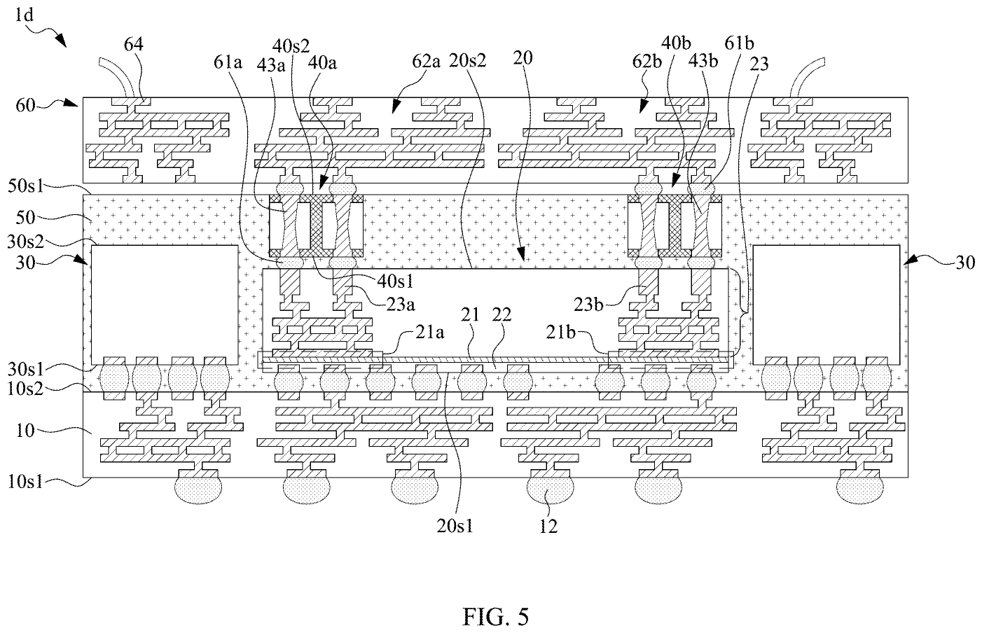

FIG. 5 illustrates a cross-sectional view of an electronic device 1d according to some embodiments of the present disclosure. The electronic device 1d is similar to the electronic device 1c as shown in FIG. 3, with differences therebetween as follows.

In some embodiments, the circuit structure 60 may include a signal delivery trace 64 (or a circuit region). The signal delivery trace 64 may be electrically connected to an external device (not shown). In some embodiments, the signal delivery trace 64 may be configured to receive and/or transmit a signal (e.g., a non-power signal), facilitating the communication between different electronic components.

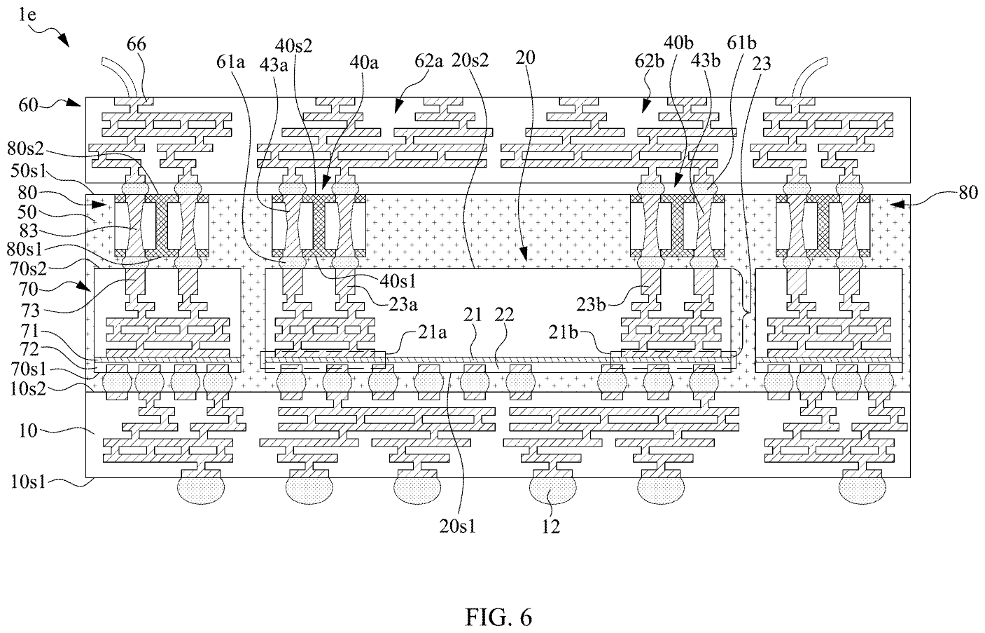

FIG. 6 illustrates a cross-sectional view of an electronic device 1e according to some embodiments of the present disclosure. The electronic device 1e is similar to the electronic device 1b as shown in FIG. 3, with differences therebetween as follows.

In some embodiments, the circuit structure 60 may include a power delivery trace 66 (or a circuit region). The power delivery trace 66 may be electrically connected to the interposer 80. The power delivery trace 66 may be electrically connected to the electronic component 70. The power delivery trace 66 may be configured to transmit power (or a power signal) to the electronic component 70 through the interposer 80.

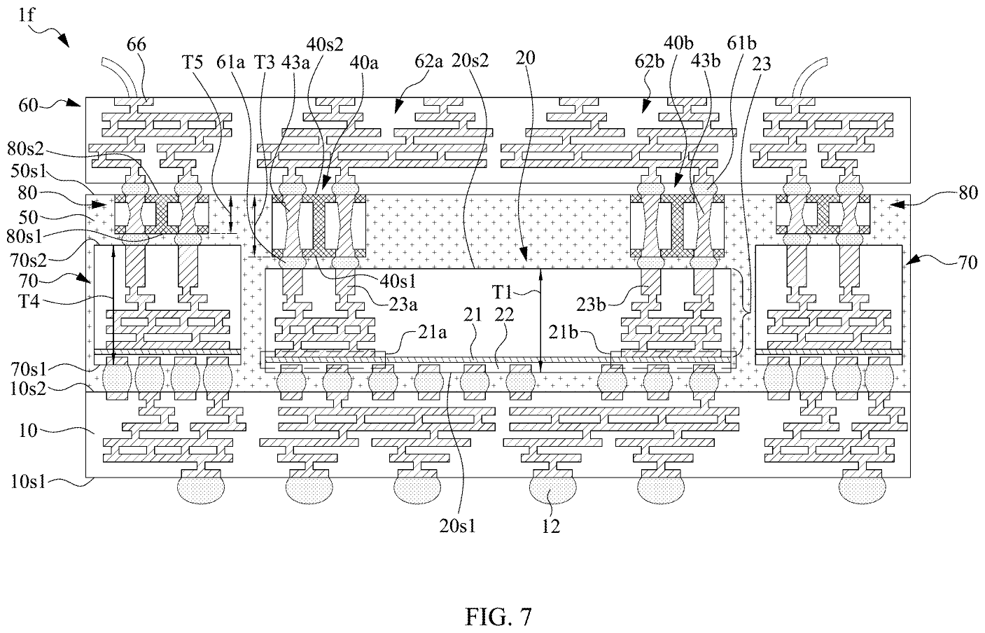

FIG. 7 illustrates a cross-sectional view of an electronic device if according to some embodiments of the present disclosure. The electronic device if is similar to the electronic device 1b as shown in FIG. 3, with differences therebetween as follows.

In some embodiments, the electronic component 70 may have a thickness T4 greater than the thickness T1 of the electronic component 20. In some embodiments, the interposer 80 may have a thickness T5 less than the thickness T3 of the interposer 40a. In some embodiments, the surface 80s1 may be located at a height different from that of the surface 40s1 of the interposer 40a with respect to the circuit structure 10. The surface 80s2 may be located at a height which is the same as that of the surface 40s2 of the interposer 40a with respect to the circuit structure 10.

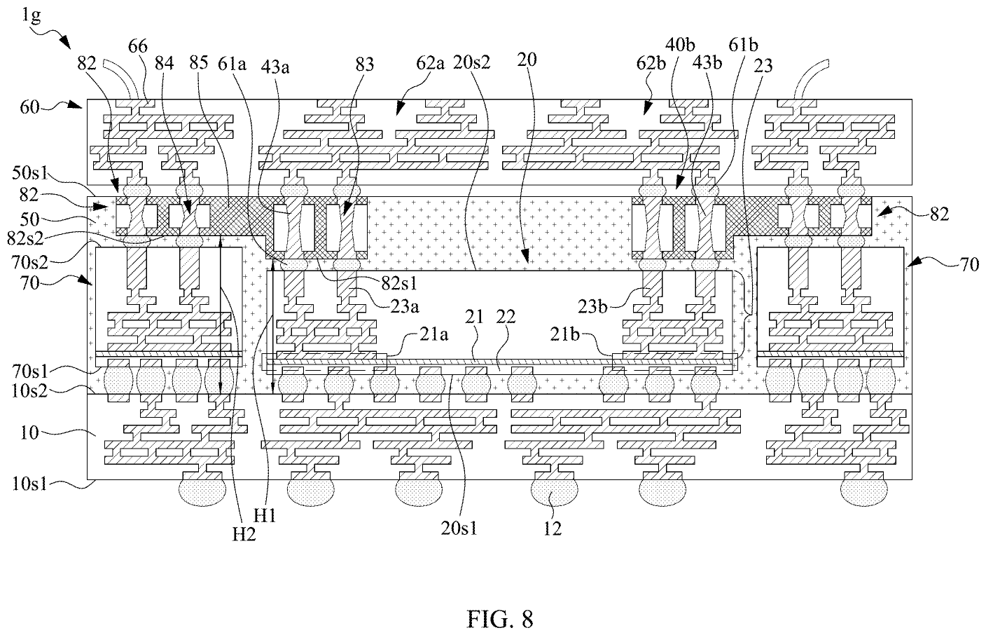

FIG. 8 illustrates a cross-sectional view of an electronic device 1g according to some embodiments of the present disclosure. The electronic device 1g is similar to the electronic device 1a as shown in FIG. 1, with differences therebetween as follows.

In some embodiments, the electronic device 1g may include an interposer 82. The interposer 82 may include a power delivery circuit 83 and a power delivery circuit 84. The power delivery circuit 83 may be electrically connected to the electronic component 20. The power delivery circuit 84 may be electrically connected to the electronic component 70. The interposer 82 may include a connection part 85. The connection part 85 may extend between the power delivery circuits 83 and 84. The interposer 82 may have a surface 82s1 and a surface 82s2. The surface 82s1 may face the electronic component 20. The surface 82s2 may face the electronic component 70. The surface 82s1 may have a height H1 with respect to the surface 10s2 of the circuit structure 10. The surface 82s2 may have a height H2 with respect to the surface 10s2 of the circuit structure 10. In some embodiments, the height H1 may be different from the height H2.

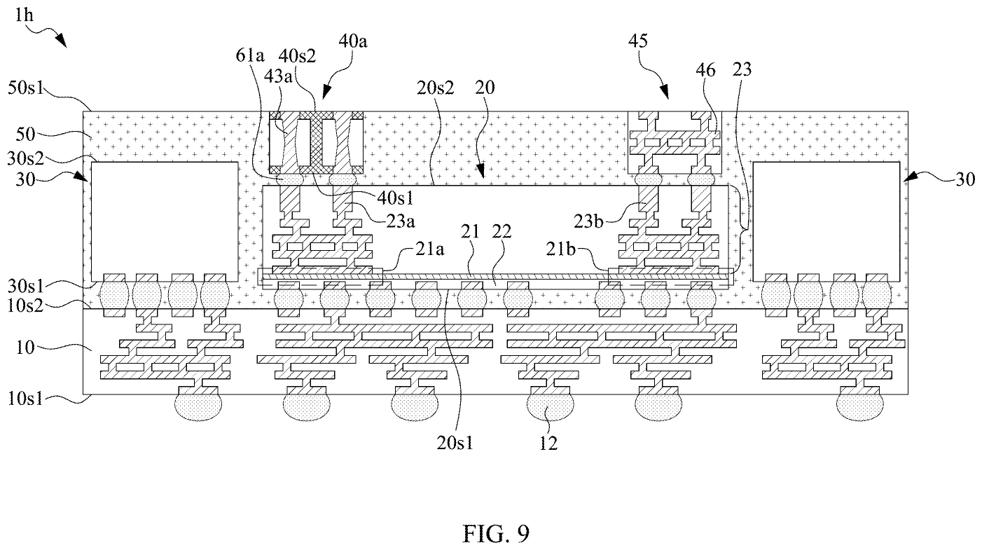

FIG. 9 illustrates a cross-sectional view of an electronic device 1h according to some embodiments of the present disclosure. The electronic device 1h is similar to the electronic device 1a as shown in FIG. 1, with differences therebetween as follows.

The electronic device 1h may include an interposer 45. In some embodiments, the interposer 45 may include a power delivery circuit 46. The power delivery circuit 46 may have two or more layers of conductive traces and/or conductive vias. In some embodiments, the number of conductive traces (or conductive layers) of the interposer 45 may be different from that of the interposer 40a. In some embodiments, the line/space (L/S) of the interposer 45 may be different from that of the interposer 40a. The line/space of a conductive structure may be defined as a pitch, a distance, or a density of a conductive structure which includes two or more conductive layers, conductive vias, or other conductive materials.

It should be noted that the interposers 40a, 40b, 45, 80, and 82 as shown in FIG. 1, FIG. 2A, and FIG. 3 to FIG. 9 may include a core layer, a solder resist, and traces embedded within the core layer and include a structure the same or similar to that as shown in FIG. 2B.

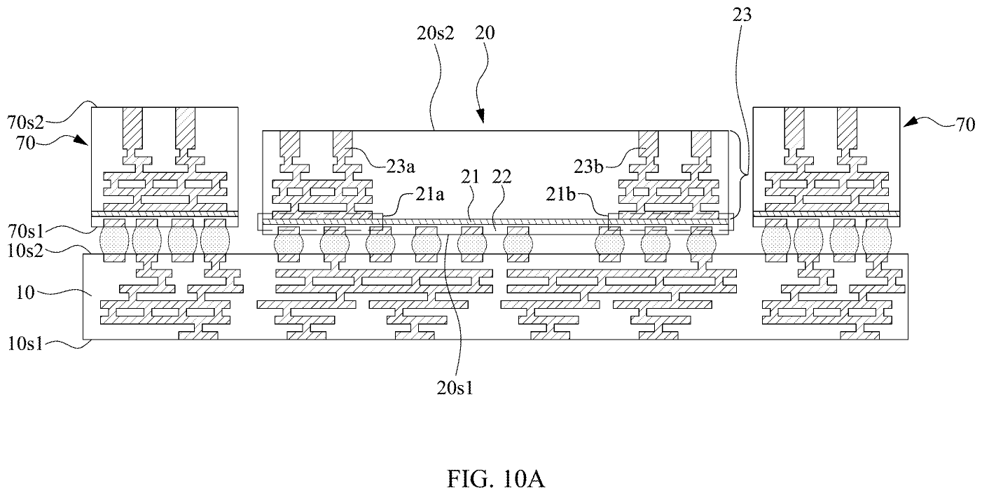

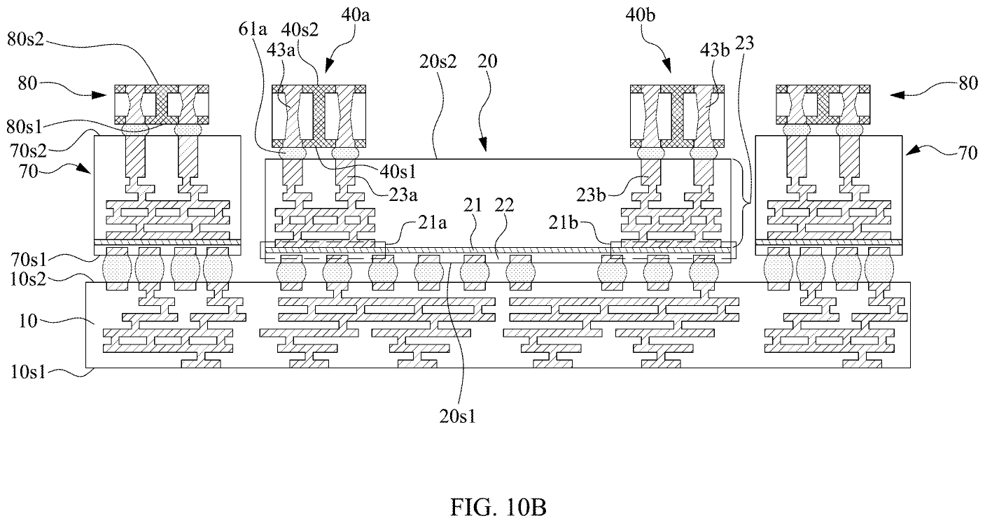

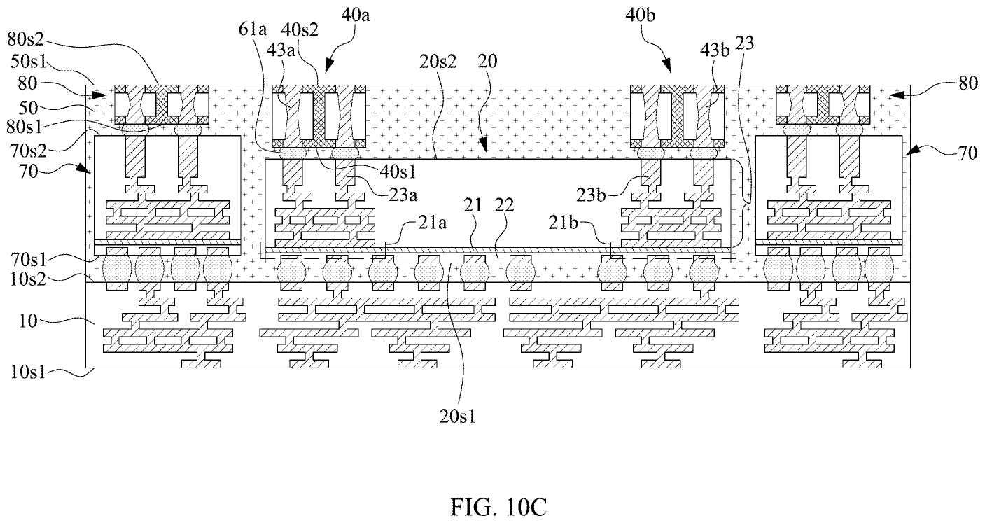

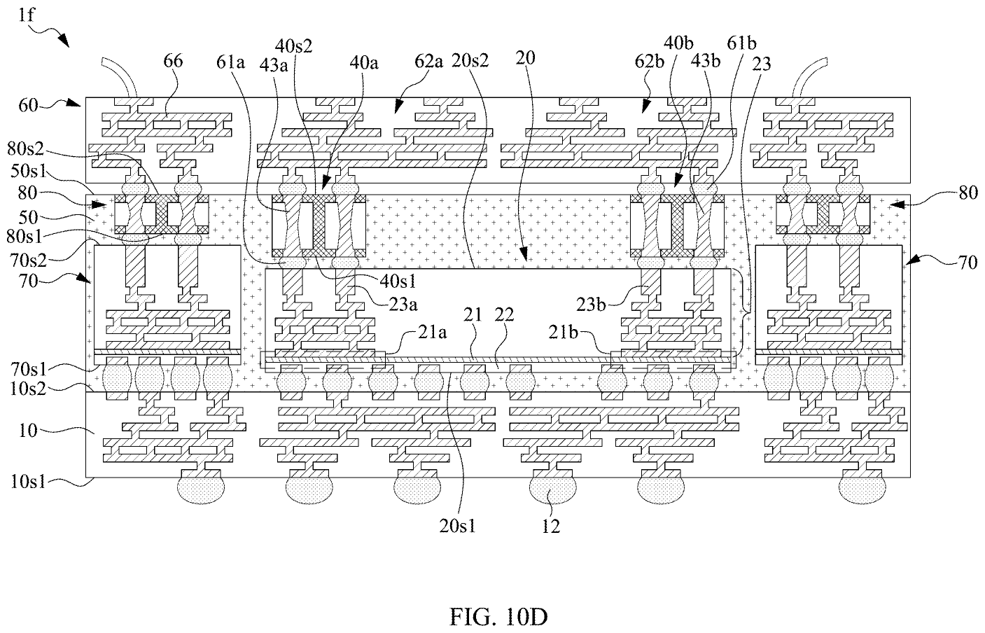

FIG. 10A, FIG. 10B, FIG. 10C, and FIG. 10D illustrate one or more stages of an example of a method for manufacturing an electronic device according to some embodiments of the present disclosure.

Referring to FIG. 10A, the circuit structure 10 may be provided or received. The electronic component 20 may be attached to the surface 10s2 of the circuit structure 10 by, for example, a flip-chip technique or other suitable techniques. The electronic component 70 may be attached to the surface 10s2 of the circuit structure 10 by, for example, a flip-chip technique or other suitable techniques.

Referring to FIG. 10B, the interposers 40a and 40b may be attached to the surface 20s2 of the electronic component 20. The interposer 80 may be attached to the surface 70s2 of the electronic component 70.

Referring to FIG. 10C, the encapsulant 50 may be formed on the surface 10s2 to encapsulate the electronic component 20, interposers 40a and 40b, electronic component 70, and the interposer 80. In some embodiments, a grinding technique may be performed on the encapsulant 50 to expose the interposers 40a and 40b.

Referring to FIG. 10D, the circuit structure 60 may be attached to the surface 50s1 of the encapsulant 50. The electrical connectors 12 may be formed under the surface 10s1 of the circuit structure 10. As a result, an electronic device, such as the electronic device if as shown in FIG. 7, may be produced.

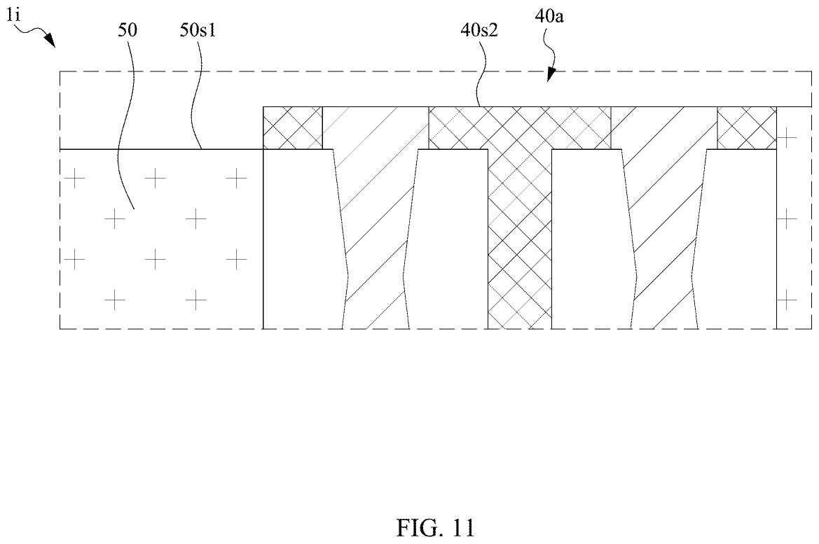

FIG. 11 illustrates an electronic device 1i according to some embodiments of the present disclosure. When an exposed molding technique is performed to form the encapsulant 50 at the stage as shown in FIG. 10C, the surface 50s1 of the encapsulant 50 may be lower than the surface 40s2 of the interposer 40a.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to +5%, less than or equal to +4%, less than or equal to +3%, less than or equal to +2%, less than or equal to +1%, less than or equal to ±0.5%, less than or equal to ±0.1%, or less than or equal to ±0.05%. For example, two numerical values can be deemed to be “substantially” the same or equal if a difference between the values is less than or equal to +10% of an average of the values, such as less than or equal to +5%, less than or equal to +4%, less than or equal to +3%, less than or equal to +2%, less than or equal to ±1%, less than or equal to ±0.5%, less than or equal to ±0.1%, or less than or equal to +0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
an interposer; and
a first electronic component disposed under the interposer and comprising a logic circuit and a power delivery circuit disposed between the interposer and the logic circuit, wherein the interposer and the power delivery circuit are collectively configured to function as a power delivery structure to electrically connect the logic circuit.

2. The electronic device of claim 1, further comprising:
an encapsulant encapsulating the interposer and the first electronic component, wherein a portion of the encapsulant is within a gap between the first electronic component and the interposer.

3. The electronic device of claim 1, wherein a portion of an upper surface of the power delivery circuit is exposed by the interposer.

4. The electronic device of claim 1, wherein the interposer is connected to the power delivery circuit by a soldering material.

5. The electronic device of claim 3, wherein a quantity of conductive layers of the interposer is different from that of the power delivery circuit.

6. The electronic device of claim 1, further comprising:
a second electronic component adjacent to the first electronic component, wherein an elevation of an upper surface of the second electronic component is higher than an elevation of an upper surface of the first electronic component.

7. The electronic device of claim 6, further comprising:
an encapsulant encapsulating the interposer, the first electronic component, and the second electronic component, wherein a distance between an upper surface of the encapsulant and the upper surface of the second electronic component is less than a distance between the upper surface of the encapsulant and the upper surface of the first electronic component.

8. The electronic device of claim 7, wherein an upper surface of the interposer is exposed by the encapsulant.

9. An electronic device, comprising:
a first electronic component comprising a logic circuit and a first power delivery circuit electrically connected to the logic circuit;
a first interposer disposed over the first electronic component and electrically connected to the first power delivery circuit; and
a second interposer disposed over the first electronic component and electrically connected to the first power delivery circuit, wherein the second interposer is spaced apart from the first interposer.

10. The electronic device of claim 9, wherein the first power delivery circuit is disposed between the logic circuit and the first interposer, and the first power delivery circuit is disposed between the logic circuit and the second interposer.

11. The electronic device of claim 9, wherein the first power delivery circuit comprises a first portion electrically connected to the first interposer and the logic circuit and a second portion electrically connected to the second interposer and the logic circuit, and wherein the first portion is spaced apart from the second portion.

12. The electronic device of claim 11, wherein the logic circuit comprises a first circuit region electrically connected to the first portion and a second circuit region electrically connected to the second portion, wherein a function of the first circuit region is different from a function of the second circuit region.

13. The electronic device of claim 9, further comprising:
a first circuit structure disposed over and electrically connected to the first interposer and the second interposer, wherein the first circuit structure covers a gap between the first interposer and the second interposer.

14. The electronic device of claim 9, wherein the first interposer comprises a second power delivery circuit, the second interposer comprises a third power delivery circuit, and a density of the second power delivery circuit is different from that of the third power delivery circuit.

15. The electronic device of claim 9, further comprising:
an encapsulant disposed between the first interposer and the second interposer, wherein the encapsulant encapsulates a lateral surface of the first electronic component.

16. The electronic device of claim 13, further comprising:
a second electronic component covered by the first circuit structure and electrically connected to the first electronic component.

17. The electronic device of claim 16, further comprising:
a second circuit structure supporting the first electronic component and the second electronic component.

18. An electronic device, comprising:
an electronic component comprising a logic circuit and a first power delivery circuit electrically connected to the logic circuit; and
an interposer disposed over the electronic component and comprising a second power delivery circuit electrically connected to the first power delivery circuit, wherein an upper surface of the first power delivery circuit is without vertically overlapping the interposer.

19. The electronic device of claim 18, wherein the electronic component has a first surface and a second surface opposite to the first surface, the logic circuit is closer to the first surface than to the second surface, and the interposer is configured to provide the logic circuit with a power through the second surface.

20. The electronic device of claim 18, wherein a portion of the logic circuit is without vertically overlapping the interposer.
